(19) United States
(12) Patent Application Publication
(10) Pub. No.: US 2026/0150565 A1
(43) Pub. Date: May 28, 2026

(54) DISPLAY DEVICE

(71) Applicant: Sharp Display Technology Corporation, Kameyama City, Mie (JP)

(72) Inventor: Kohzoh NAKAMURA, Kameyama City, Mie (JP)

(21) Appl. No.: 19/121,192

(22) PCT Filed: Oct. 21, 2022
(86) PCT No.: PCT/JP2022/039258

§ 371 Date: Apr. 15, 2025

(51) Int. Cl. H10K 59/80; H10K 39/34; H10K 50/115

(52) U.S. Cl. CPC H10K 59/8791; H10K 39/34; H10K 50/115; H10K 59/8051

(57) ABSTRACT

A display device includes an imaging element layer, a light-emitting element layer located closer to a display surface side than the imaging element layer, a selective reflection layer located between the imaging element layer and the light-emitting element layer and transmitting one of right-handed circularly-polarized light and left-handed circularly-polarized light and reflecting the other, and a retardation layer located between the selective reflection layer and the light-emitting element layer and having a switchable phase difference.

### TECHNICAL FIELD

The disclosure relates to a display device including an imaging element layer and a light-emitting element layer located closer to a display surface side than the imaging element layer.

### BACKGROUND ART

There is known a display device including a light-emitting element layer that emits circularly-polarized light, a transparent substrate located on a side opposite to a display surface with respect to the light-emitting element layer, and a selective reflection layer located on a side opposite to the display surface with respect to the transparent substrate (PTL 1).

### Citation List

### Patent Literature

PTL 1: JP 2012-506129 T

### SUMMARY

### Technical Problem

When an imaging element layer is provided on the side opposite to a display surface of a light-emitting element layer that emits non-polarized light, there is a configuration in which an anode between the light-emitting element layer and the imaging element layer is a transparent electrode in order to increase the transmittance of external light traveling toward the imaging element layer. This has a problem in that of the non-polarized light emitted from the light-emitting element layer, the light traveling toward the side opposite to the display surface is not reflected by the anode, but passes through the anode and further travels toward the side opposite to the display surface; therefore, the luminance based on the non-polarized light emitted from the light-emitting element layer is substantially halved.

### Solution to Problem

In order to solve the problem above, according to an aspect of the disclosure, there is provided a display device including: an imaging element layer; a light-emitting element layer located closer to a side of a display surface than the imaging element layer; a selective reflection layer located between the imaging element layer and the light-emitting element layer and configured to transmit one of right-handed circularly-polarized light and left-handed circularly-polarized light and reflect the other of the right-handed circularly-polarized light and the left-handed circularly-polarized light; and a retardation layer located between the selective reflection layer and the light-emitting element layer and having a switchable phase difference.

### Advantageous Effects of Disclosure

The display device according to an aspect of the disclosure can suppress a decrease in luminance based on non-polarized light emitted from the light-emitting element layer while increasing the transmittance of external light traveling toward the imaging element layer.

### BRIEF DESCRIPTION OF DRAWINGS

FIG. 1 is a front view of a display device according to an embodiment.

FIG. 2 is a cross-sectional view of a camera region disposed on a display surface of the display device.

FIG. 3 is a cross-sectional view of a normal region and a peripheral region disposed on the display surface.

FIG. 4 is a circuit diagram of the display device.

FIG. 5A is a cross-sectional view of the camera region of display device.

FIG. 5B is a cross-sectional view of the normal region and the peripheral region of the display device.

FIG. 6 is a schematic view for explaining the definition of a polarization direction of light according to the display device.

FIG. 7 is a schematic view for explaining the behavior of circularly-polarized light according to the display device.

FIG. 8 is a cross-sectional view for explaining an operation in an imaging mode of the display device.

FIG. 9 is a cross-sectional view for explaining an operation in a display mode of the display device.

FIG. 10 is a cross-sectional view of a camera region disposed on a display surface of a display device according to a second embodiment.

FIG. 11 is a cross-sectional view of a camera region disposed on a display surface of a variation of the display device.

### DESCRIPTION OF EMBODIMENTS

### First Embodiment

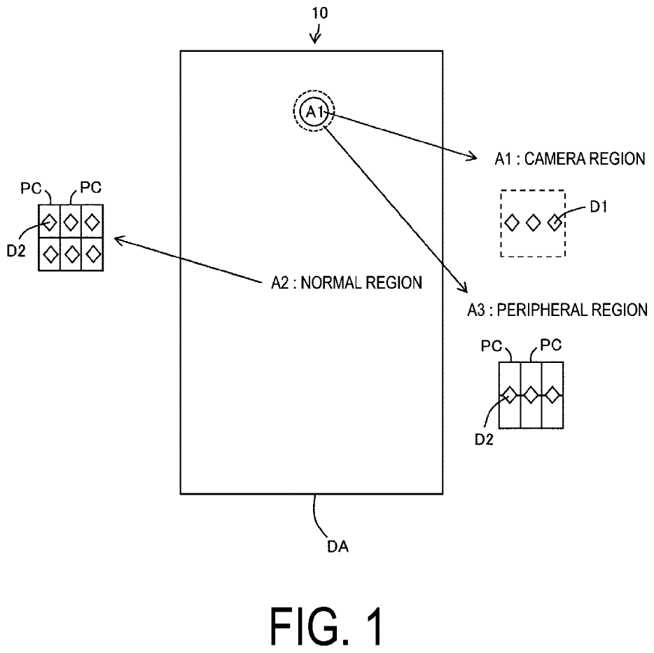

FIG. 1 is a front view of a display device 10 according to a first embodiment.

The display device 10 includes a display surface DA. As illustrated in FIG. 1, the display surface DA includes a circular camera region A1 disposed at a position corresponding to a camera provided on a back surface side of the display device 10, an annular peripheral region A3 formed along an outer edge of the camera region A1, and a normal region A2 including a region of the display surface DA other than the camera region A1 and the peripheral region A3.

A plurality of first light-emitting elements D1 are disposed in the camera region A1. A plurality of second light-emitting elements D2 are disposed in each of the normal region A2 and the peripheral region A3.

In the normal region A2, pixel circuits PCs for driving the second light-emitting elements D2 are provided in one-to-one correspondence with the plurality of second light-emitting elements D2. Pixel circuits PCs for driving the first light-emitting elements D1 are not provided in the camera region A1. In the peripheral region A3, pixel circuits PCs for driving the second light-emitting elements D2 disposed in the peripheral region A3 and pixel circuits PCs for driving the first light-emitting elements D1 disposed in the camera region A1 are provided.

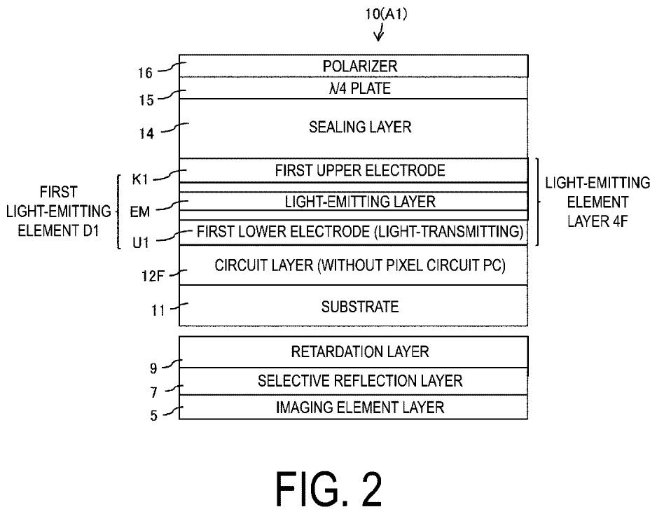

FIG. 2 is a cross-sectional view of the camera region A1 disposed on the display surface DA of the display device 10.

The display device 10 includes an imaging element layer 5 corresponding to the camera, a light-emitting element layer 4F located closer to the display surface DA side than the imaging element layer 5, a selective reflection layer 7 located between the imaging element layer 5 and the light-emitting element layer 4F and transmitting right-handed circularly-polarized light and reflecting left-handed circularly-polarized light, and a retardation layer 9 located between the selective reflection layer 7 and the light-emitting element layer 4F and having a switchable phase difference. The selective reflection layer 7 may transmit the left-handed circularly-polarized light and reflect the right-handed circularly-polarized light. The selective reflection layer 7 is a cholesteric selective reflection layer. As the cholesteric selective reflection layer, for example, NIPOCS (registered trademark, available from Nitto Denko Corporation) or a cholesteric liquid crystal film (available from ENEOS LC COMPANY, LIMITED) can be used. The imaging element layer 5 includes an imaging element that images external light that has passed through the light-emitting element layer 4F.

The light-emitting element layer 4F includes a first light-emitting element D1 overlapping the imaging element layer 5 in a plan view. The first light-emitting element D1 includes a light-transmitting first lower electrode U1, a first upper electrode K1 located closer to the display surface DA side than the first lower electrode U1, and a light-emitting layer EM (first light-emitting layer) located between the first lower electrode U1 and the first upper electrode K1. The light-emitting layer EM is an organic light-emitting layer including an organic light-emitting diode (OLED), or a quantum dot light-emitting layer including a quantum dot light-emitting diode (QLED). The light-emitting layer EM emits non-polarized light.

The first lower electrode U1 is preferably a transparent anode.

The retardation layer 9 has a phase difference of 0 in the imaging mode by the imaging element layer 5 and has a phase difference of π in the display mode. The phase difference may be π×(2n−1) (n is a natural number) in which the ordinary light and the extraordinary light are shifted by a half-wavelength. The retardation layer 9 is a liquid crystal layer.

The first light-emitting element D1 is not turned on in the imaging mode by the imaging element layer 5, and is turned on in accordance with the display gray scale in the display mode.

The display device 10 further includes a substrate 11 provided between the light-emitting element layer 4F and the retardation layer 9, and a circuit layer 12F provided between the substrate 11 and the first lower electrode U1. The circuit layer 12F is provided in the above-described camera region A1, and the pixel circuit PC for driving the light-emitting layer EM is not formed in the circuit layer 12F.

The display device 10 further includes a polarizer 16 (linear polarizer) located closer to the display surface DA side than the light-emitting element layer 4F. The display device 10 further includes a λ/4 plate 15 located between the light-emitting element layer 4F and the polarizer 16.

It is preferable that the transmission axis of the polarizer 16 and the slow axis of the λ/4 plate 15 form an angle of 45 degrees.

In the imaging mode, the circularly-polarized light which has passed through the polarizer 16 and the λ/4 plate 15 and whose phase has not been changed by the retardation layer 9 passes through the selective reflection layer 7 and enters the imaging element layer 5.

In the display mode, the circularly-polarized light reflected by the selective reflection layer 7 and phase-shifted by π by the retardation layer 9 is converted into linearly-polarized light by the λ/4 plate 15 and passes through the polarizer 16.

The display device 10 further includes a sealing layer 14 provided between the first upper electrode K1 and the λ/4 plate 15.

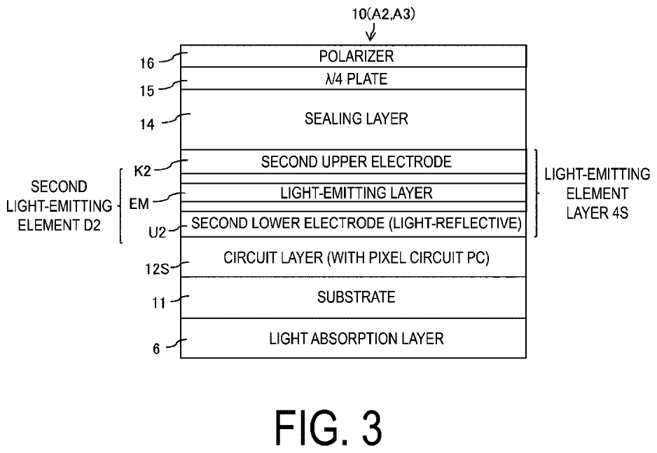

FIG. 3 is a cross-sectional view of the normal region A2 and the peripheral region A3 disposed on the display surface DA of the display device 10. The same components as the above-described components are denoted by the same reference numerals, and detailed description of the components is not repeated.

The display device 10 includes a light-emitting element layer 4S in the normal region A2 and the peripheral region A3. The light-emitting element layer 4S includes the second light-emitting element D2 that does not overlap the imaging element layer 5 in a plan view. The second light-emitting element D2 includes a light-reflective second lower electrode U2, a second upper electrode K2 located closer to the display surface DA side than the second lower electrode U2, and a light-emitting layer EM (second light-emitting layer) located between the second lower electrode U2 and the second upper electrode K2.

The display device 10 further includes a circuit layer 12S provided between the substrate 11 and the second lower electrode U2. The circuit layer 12S is provided in the normal region A2 and the peripheral region A3 described above, and the pixel circuit PC for driving the light-emitting layer EM is formed in the circuit layer 12S.

The display device 10 includes, below the selective reflection layer 7, a light absorption layer 6 that overlaps the second lower electrode U2 and does not overlap the first lower electrode U1 in a plan view.

The selective reflection layer 7 overlaps the first lower electrode Ul and does not overlap the second lower electrode U2 in a plan view. The retardation layer 9 overlaps the first lower electrode U1 and does not overlap the second lower electrode U2 in a plan view.

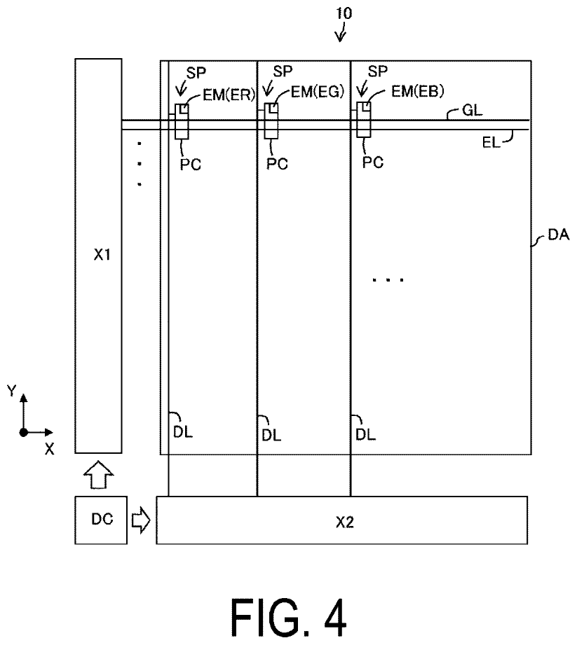

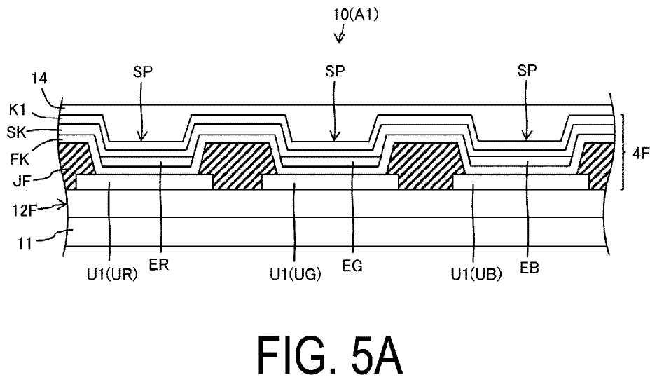

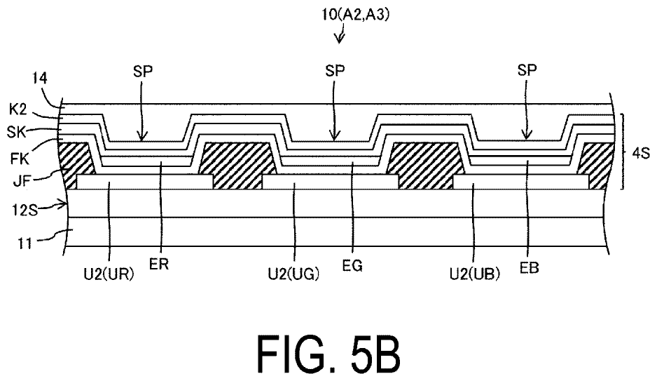

FIG. 4 is a circuit diagram of the display device 10. FIG. 5A is a cross-sectional view of the camera region A1 of the display device 10. FIG. 5B is a cross-sectional view of the normal region A2 and the peripheral region A3 of the display device 10. The same components as the above-described components are denoted by the same reference numerals, and detailed description of the components is not repeated.

The display device 10 includes a plurality of gate lines GL formed, in the display region DA, parallel to each other along the X direction, a plurality of data lines DL formed, in the display region DA, parallel to each other along the Y direction, a driver X1 for driving the plurality of gate lines GL, a driver X2 for driving the plurality of data lines DL, and a power supply DC for supplying power to the drivers X1 and X2.

A subpixel SP is disposed at each of a plurality of locations where the plurality of gate lines GL and the plurality of data lines DL intersect with each other. Each subpixel SP is provided with the light-emitting layer EM and the pixel circuit PC for driving the light-emitting layer EM. The light-emitting layer EM can be, for example, any one of a light-emitting layer ER that emits red light, a light-emitting layer EG that emits green light, and a light-emitting layer EB that emits blue light.

Charge transport layers SK and FK, the first upper electrode K1, and the second upper electrode K2 are provided in common for the plurality of subpixels SP. The light-emitting layers ER, EG, and EB and the second lower electrodes UR, UG, and UB are provided for respective subpixels SP. Bank JFs are provided so as to cover the edges of the second lower electrodes UR, UG, and UB.

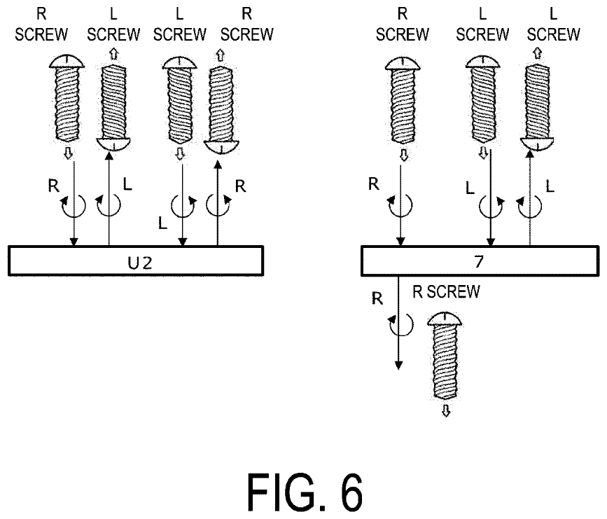

FIG. 6 is a schematic view for explaining the definition of the polarization direction of light according to the display device 10. The same components as the above-described components are denoted by the same reference numerals, and detailed description of the components is not repeated.

Here, the polarization direction of light according to the display device 10 is defined. In the present specification, the polarization direction of light means the polarization direction when viewed along the traveling direction of light. For example, when the polarization direction when viewed along the traveling direction of the light is clockwise, the polarization direction of the light is right-handed circularly-polarized light, and when the polarization direction is counterclockwise, the polarization direction of the light is left-handed circularly-polarized light.

For example, as illustrated in FIG. 6, in the case where light is incident toward the light-reflective second lower electrode U2, when the polarization direction of the light is clockwise when viewed in the downward direction, which is the traveling direction of the light, the polarization direction of the light is right-handed circularly-polarized light. The polarization direction of the light reflected by the second lower electrode U2 when viewed in the upward direction, which is the traveling direction of the light, is counterclockwise, and the polarization direction of the light is left-handed circularly-polarized light.

Note that when a viewer views the light reflected by the second lower electrode U2 in the downward direction opposite to the traveling direction of the reflected light, the polarization direction of the reflected light appears to be clockwise instead of counterclockwise. However, in the present specification, the reflected light is referred to as left-handed circularly-polarized light instead of right-handed circularly-polarized light.

That is, the right-handed circularly-polarized light incident on the second lower electrode U2 is reflected as left-handed circularly-polarized light. Similarly, the left-handed circularly-polarized light incident on the second lower electrode U2 is reflected as right-handed circularly-polarized light.

In the case where light is incident toward the selective reflection layer 7, when the polarization direction of the light is clockwise when viewed in the downward direction, which is the traveling direction of the light, the polarization direction of the light is right-handed circularly-polarized light, and the selective reflection layer 7 transmits the right-handed circularly-polarized light as it is.

When the polarization direction of the light is counterclockwise when viewed in the downward direction, which is the traveling direction of the light, the polarization direction of the light is left-handed circularly-polarized light, and the selective reflection layer 7 reflects the left-handed circularly-polarized light as it is. The polarization direction of the light reflected by the selective reflection layer 7 is counterclockwise when viewed in the upward direction, which is the traveling direction of the light.

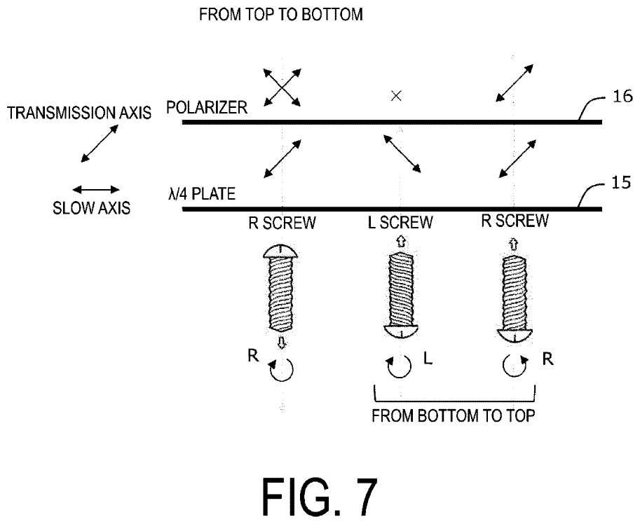

FIG. 7 is a schematic view for explaining the behavior of circularly-polarized light according to the display device 10. The same components as the above-described components are denoted by the same reference numerals, and detailed description of the components is not repeated.

As illustrated in FIG. 7, circularly-polarized light incident on the display surface DA of the display device 10 from the outside passes through the polarizer 16 and then passes through the λ/4 plate 15 to become right-handed circularly-polarized light.

The light-emitting layer EM of the display device 10 emits non-polarized light. After the non-polarized light passes through the retardation layer 9, the light is reflected by the selective reflection layer 7, passes through the retardation layer 9 again, and goes to the outside. The light is left-handed circularly-polarized light. Then, as indicated by an L screw in FIG. 7, the light passes through the λ/4 plate 15 and then is blocked by the polarizer 16. On the other hand, as illustrated by an R screw in FIG. 7, the light traveling to the outside, which is right-handed circularly-polarized light, becomes linearly-polarized light parallel to the transmission axis of the polarizer 16 after passing through the λ/4 plate 15, passes through the polarizer 16, and travels to the viewer side.

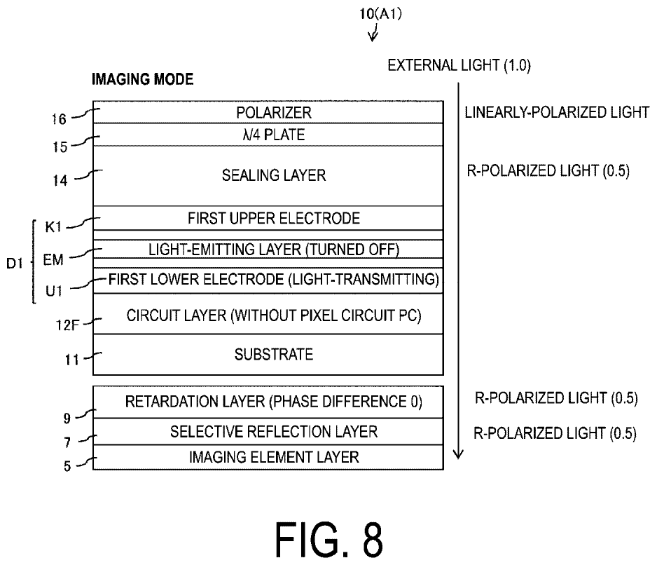

FIG. 8 is a cross-sectional view for explaining an operation of the display device 10 in the imaging mode. The same components as the above-described components are denoted by the same reference numerals, and detailed description of the components is not repeated.

In the imaging mode during imaging by a camera corresponding to the imaging element layer 5, the light-emitting layer EM is turned off. In the retardation layer 9, the phase difference between ordinary light and extraordinary light is 0. The selective reflection layer 7 transmits right-polarized light and reflects left-polarized light.

First, when non-polarized external light passes through the polarizer 16, it becomes linearly-polarized light and the luminance decreases from 1.0 to 0.5. Then, when the linearly polarized light passes through the λ/4 plate 15 whose slow axis forms an angle of 45 degrees with the transmission axis of the polarizer 16, the linearly-polarized light becomes right-polarized light having a luminance of 0.5, and passes through the first light-emitting element D1, the circuit layer 12F, and the substrate 11 in this order. Next, the right-polarized light passes through the retardation layer 9 having a phase difference of 0 without being changed in phase. Thereafter, the light passes through the selective reflection layer 7 which transmits the right-polarized light as it is and reflects the left-polarized light, and the right-polarized light is incident on the imaging element layer 5 at a luminance of 0.5.

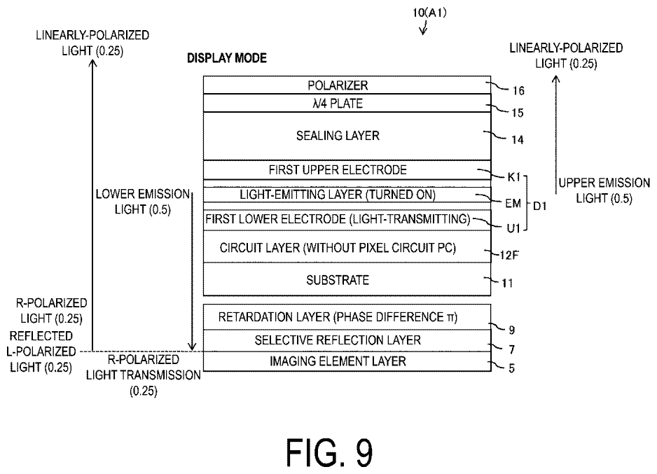

FIG. 9 is a cross-sectional view for explaining an operation of the display device 10 in the display mode. The same components as the above-described components are denoted by the same reference numerals, and detailed description of the components is not repeated.

In a normal display mode other than imaging by the camera, the light-emitting layer EM is turned on. The retardation layer 9 is electrically switched from the imaging mode to the display mode, and the phase difference is switched from 0 to π. The selective reflection layer 7 transmits the right-polarized light and reflects the left-polarized light as in the imaging mode.

First, when non-polarized external light passes through the polarizer 16, it becomes linearly-polarized light, and the luminance decreases from 1.0 to 0.5, as in the imaging mode. After passing through the λ/4 plate 15, the linearly-polarized light becomes right-polarized light having a luminance of 0.5, and passes through the first light-emitting element D1, the circuit layer 12F, and the substrate 11 in this order.

Next, the right-polarized light passes through the retardation layer 9 whose phase difference is switched from 0 to π, and is emitted as left-polarized light. Thereafter, the left-polarized light is reflected by the selective reflection layer 7. The left-polarized light reflected by the selective reflection layer 7 passes through the retardation layer 9 whose phase difference is switched to π and is emitted as right-polarized light. Then, the right-polarized light having passed through the substrate 11, the circuit layer 12F, the first light-emitting element D1, and the sealing layer 14 in this order passes through the λ/4 plate 15 and the polarizer 16 and is emitted to the outside of the display device 10 at a luminance of 0.5.

As a result, a part of the external light incident from the outside is reflected by the selective reflection layer 7 and exits to the outside again, and thus the antireflective effect of external light by the polarizer 16 is reduced by half, but since the camera region A1 is a region having an area of 0.1% or less of the entire display surface DA, the deterioration of image quality does not become a serious problem in practical use. Although there is no incident light on the imaging element layer 5 corresponding to the camera, there is no problem because imaging is not performed by the camera.

The non-polarized light having a luminance of 0.5 emitted from the light-emitting layer EM toward the first lower electrode U1 side passes through the retardation layer 9. Of the non-polarized light, the light having passed through the selective reflection layer 7 becomes right-handed circularly-polarized light having a luminance of 0.25. On the other hand, the light reflected by the selective reflection layer 7 becomes left-handed circularly-polarized light having a luminance of 0.25. The left-polarized light having a luminance of 0.25 reflected by the selective reflection layer 7 passes through the retardation layer 9 whose phase difference has been switched to π and becomes right-polarized light having a luminance of 0.25. The right-polarized light passes through the substrate 11, the circuit layer 12F, the first light-emitting element D1, and the sealing layer 14 in this order, passes through the λ/4 plate 15 to become linearly-polarized light, passes through the polarizer 16, and is emitted as linearly-polarized light having a luminance of 0.25 to the outside of the display device 10.

On the other hand, the non-polarized light having a luminance of 0.5 emitted from the light-emitting layer EM to the first upper electrode K1 side passes through the λ/4 plate 15 and the polarizer 16 and is emitted as linearly-polarized light having a luminance of 0.25 to the outside of the display device 10. Therefore, the total luminance of light emitted from the light-emitting layer EM to the outside of the display device 10 is 0.5.

### Second Embodiment

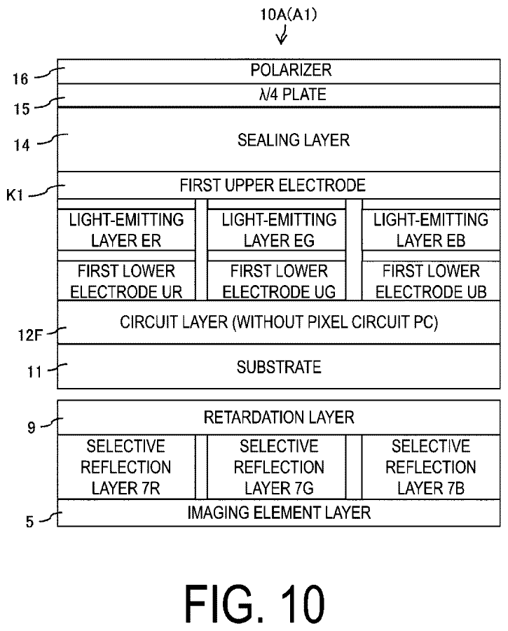

FIG. 10 is a cross-sectional view of a camera region A1 disposed on a display surface DA of a display device 10A according to a second embodiment. The same components as the above-described components are denoted by the same reference numerals, and detailed description of the components is not repeated.

The display device 10A includes a light-emitting layer EB for emitting blue light, a light-emitting layer EG for emitting green light, a light-emitting layer ER for emitting red light, a first lower electrode UB corresponding to the light-emitting layer EB, a first lower electrode UG corresponding to the light-emitting layer EG, a first lower electrode UR corresponding to the light-emitting layer ER, and a first upper electrode K1 provided in common for the light-emitting layers EB, EG, and ER.

The display device 10A includes a selective reflection layer 7B (first layer) that transmits right-handed circularly-polarized light and reflects left-handed circularly-polarized light for blue light (light in the first wavelength range), a selective reflection layer 7G (second layer) that transmits right-handed circularly-polarized light and reflects left-handed circularly-polarized light for green light (light in the second wavelength range), and a selective reflection layer 7R (third layer) that transmits right-handed circularly-polarized light and reflects left-handed circularly-polarized light for red light (light in the third wavelength range).

The green wavelength range (second wavelength range) is located on the longer wavelength side than the blue wavelength range (first wavelength range), and the red wavelength range (third wavelength range) is located on the longer wavelength side than the green wavelength range (second wavelength range).

As described above, the selective reflection layers 7R, 7G, and 7B may be provided for the light-emitting layers ER, EG, and EB, respectively.

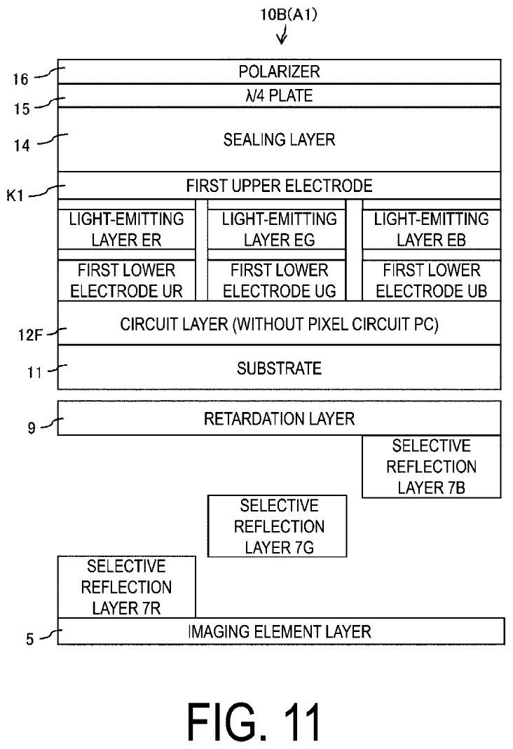

FIG. 11 is a cross-sectional view of the camera region A1 disposed on the display surface DA of the display device 10B according to a variation. The same components as the above-described components are denoted by the same reference numerals, and detailed description of the components is not repeated.

The selective reflection layer 7G (second layer) is disposed at a position closer to the first lower electrodes UG and UR than the selective reflection layer 7R (third layer). The selective reflection layer 7B (first layer) is disposed at a position closer to the first lower electrodes UB and UG than the selective reflection layer 7G (second layer).

The disclosure is not limited to each of the embodiments described above, and various modifications may be made within the scope of the claims. Embodiments obtained by appropriately combining technical approaches disclosed in the different embodiments also fall within the technical scope of the disclosure. Furthermore, novel technical features can be formed by combining the technical approaches disclosed in the embodiments.

### Reference Signs List

4F Light-emitting element layer
4S Light-emitting element layer
5 Imaging element layer
6 Light absorption layer
7 Selective reflection layer
7R Selective reflection layer (first layer)
7G Selective reflection layer (second layer)
7B Selective reflection layer (third layer)
9 Retardation layer
10 Display device
15 λ/4 plate
16 Polarizer (linear polarizer)
D1 First light-emitting element
D2 Second light-emitting element
U1 First lower electrode
U2 Second lower electrode
K1 First upper electrode
K2 Second upper electrode
EM Light-emitting layer (first light-emitting layer, second light-emitting layer)

1. A display device comprising:
an imaging element layer;
a light-emitting element layer located closer to a side of a display surface than the imaging element layer;
a selective reflection layer located between the imaging element layer and the light-emitting element layer and configured to transmit one of right-handed circularly-polarized light and left-handed circularly-polarized light and reflect the other of the right-handed circularly-polarized light and the left-handed circularly-polarized light; and
a retardation layer located between the selective reflection layer and the light-emitting element layer and having a switchable phase difference.

2. The display device according to claim 1,
wherein the light-emitting element layer includes a first light-emitting element overlapping the imaging element layer in a plan view, and
the first light-emitting element includes a first lower electrode having a light-transmitting property, a first upper electrode located closer to the side of the display surface than the first lower electrode, and a first light-emitting layer located between the first lower electrode and the first upper electrode.

3. The display device according to claim 1,
wherein the retardation layer has a phase difference of 0 in an imaging mode and a phase difference of π×(2n−1) (n is a natural number) in a display mode.

4. The display device according to claim 2,
wherein the first light-emitting element is turned off in an imaging mode and is turned on in accordance with a display gray scale in a display mode.

5. The display device according to claim further comprising:
a linear polarizer located closer to the side of the display surface than the light-emitting element layer.

6. The display device according to claim 5, further comprising:
a λ/4 plate located between the light-emitting element layer and the linear polarizer.

7. The display device according to claim 2,
wherein the first lower electrode is a transparent anode.

8. The display device according to claim 6,
wherein a transmission axis of the linear polarizer and a slow axis of the λ/4 plate form an angle of 45 degrees.

9. The display device according to claim 2,
wherein the light-emitting element layer includes a second light-emitting element not overlapping the imaging element layer in a plan view, and
the second light-emitting element includes a second lower electrode having light reflectivity, a second upper electrode located closer to the side of the display surface than the second lower electrode, and a second light-emitting layer located between the second lower electrode and the second upper electrode.

10. The display device according to claim 9,
wherein the selective reflection layer overlaps the first lower electrode and does not overlap the second lower electrode in a plan view.

11. The display device according to claim 9,
wherein the retardation layer overlaps the first lower electrode and does not overlap the second lower electrode in a plan view.

12. The display device according to claim 2,
wherein the selective reflection layer includes a first layer configured to transmit one of right-handed circularly-polarized light and left-handed circularly-polarized light and reflect the other of the right-handed circularly-polarized light and the left-handed circularly-polarized light with respect to light in a first wavelength range, a second layer configured to transmit one of right-handed circularly-polarized light and left-handed circularly-polarized light and reflect the other of the right-handed circularly-polarized light and the left-handed circularly-polarized light with respect to light in a second wavelength range, and a third layer configured to transmit one of right-handed circularly-polarized light and left-handed circularly-polarized light and reflect the other of the right-handed circularly-polarized light and the left-handed circularly-polarized light with respect to light in a third wavelength range.

13. The display device according to claim 12,
wherein the second wavelength range is located on a longer wavelength side than the first wavelength range, and the third wavelength range is located on a longer wavelength side than the second wavelength range.

14. The display device according to claim 13,
wherein the second layer is closer to the first lower electrode than the third layer, and the first layer is closer to the first lower electrode than the second layer.

15. The display device according to claim 1,
wherein the selective reflection layer is a cholesteric selective reflection layer.

16. The display device according to claim 9, further comprising:
a light absorption layer below the selective reflection layer, the light absorption layer overlapping the second lower electrode and not overlapping the first lower electrode in a plan view.

17. The display device according to claim 6,
wherein, in an imaging mode, circularly-polarized light that has passed through the linear polarizer and the λ/4 plate and has not been changed in phase by the retardation layer passes through the selective reflection layer and is incident on the imaging element layer.

18. The display device according to claim 17,
wherein, in a display mode, circularly-polarized light reflected by the selective reflection layer and phase-shifted by π×(2n−1) (n is a natural number) by the retardation layer is converted into linearly-polarized light by the λ/4 plate, and the linearly-polarized light passes through the linear polarizer.

19. The display device according to claim 1,
wherein the retardation layer is a liquid crystal layer.

20. The display device according to claim 2,
wherein the first light-emitting layer is an organic light-emitting layer or a quantum dot light-emitting layer.

21. (canceled)
